(19) United States
(12) Patent Application Publication
(10) Pub. No.: US 2004/0132311 A1
(43) Pub. Date: Jul. 8, 2004

(54) Method of etching high-K dielectric materials

(75) Inventors: Padmapani C. Nallan, San Jose, CA (US); Guangxiang Jin, San Jose, CA (US); Ajay Kumar, Sunnyvale, CA (US)

Correspondence Address: Patent Counsel, Applied Materials, Inc., P.O. Box 450A, Santa Clara, CA, 95052, US

(73) Assignee: Applied Materials, Inc.

(21) Appl. No.: 10/338,250

(22) Filed: Jan. 6, 2003

(51) Int. Cl. H01L 21/302; H01L 21/461

(52) U.S. Cl. 438/710

(57) ABSTRACT

A method of etching a dielectric layer having a dielectric constant that is greater than 4.0 on a semiconductor substrate using a pulsed substrate biasing technique (PSBT) that applies a plurality of processing cycles to the substrate, where each cycle comprises a period of plasma etching without substrate bias and a period of plasma etching with the substrate bias.

### BACKGROUND OF THE INVENTION

1. Field of the Invention

The present invention generally relates to a method for fabricating devices on semiconductor substrates. More specifically, the present invention relates to a method of etching high-K dielectric materials.

2. Description of the Related Art

Ultra-large-scale integrated (ULSI) circuits typically include more than one million transistors that are formed on a semiconductor substrate and cooperate to perform various functions within an electronic device. The transistors generally are complementary metal-oxide-semiconductor (CMOS) field effect transistors. The CMOS transistor has a gate structure that is disposed between a source region and a drain region formed in the semiconductor substrate. The gate structure comprises a gate electrode and a gate dielectric. The gate electrode is provided over the gate dielectric and controls a flow of charge carriers in a channel region formed between the drain and the source regions to turn the transistor on or off. There is a constant trend to reduce a width of the channel region, as well as the width of the gate structure, to thereby increase the overall operational speed of the transistor.

The advanced CMOS transistors generally utilize polysilicon gate electrodes formed upon a gate dielectric fabricated of very thin layers of hafnium dioxide (HfO₂), hafnium silicate (HfSiO₂), and the like. Such materials have a high dielectric constant that is greater than 4.0 and are referred to as high-K materials.

To form a transistor, regions in the substrate are doped to form source and drain regions and a high-K dielectric layer is deposited over the substrate. A polysilicon layer is deposited over the dielectric layer and then an etch mask (e.g., silicon dioxide (SiO₂ mask) is formed upon the polysilicon layer. The etch mask defines the location and topographic dimensions of the gate structure. Portions of the polysilicon and high-K dielectric layers that are not protected by the mask are then selectively removed, while the remaining protected portions of the layers form, respectively, a gate electrode and gate dielectric of the CMOS transistor.

The high-K dielectric materials may be etched using a plasma comprising a halogen gas (e.g., chlorine (Cl₂), HCl, and the like), as well as a reducing gas such as carbon monoxide (CO). One such etch process is disclosed in commonly assigned U.S. patent application Ser. No. 10/194,566, filed Jul. 12, 2002 (Attorney docket number 7269), which is incorporated herein by reference. Generally, the etch process provides relatively low selectivity to high-K dielectric materials over silicon and polysilicon, as well as to silicon dioxide (e.g., selectivity of HfO₂ to Si and SiO₂ is about 3:1 and 10:1, respectively). The low selectivity of the process requires use of thicker etch masks to protect the underlying layer. The low selectivity of the process also results in unacceptable silicon recess in the source and drain regions of the device.

Therefore, there is a need in the art for an improved method for etching high-K dielectric materials for fabricating a gate structure a field effect transistor.

### SUMMARY OF THE INVENTION

A method of etching a dielectric layer having a dielectric constant that is greater than 4.0 on a semiconductor substrate using a pulsed substrate biasing technique (PSBT) that applies a plurality of processing cycles to the substrate, where each cycle comprises a period of plasma etching without substrate bias and a period of plasma etching with the substrate bias. In one application, the method is used for fabricating a gate structure of a field effect transistor to increase the etch selectivity of the gate dielectric material, such as hafnium dioxide (HfO₂), HfSiO₂, and the like.

### BRIEF DESCRIPTION OF THE DRAWINGS

The teachings of the present invention can be readily understood by considering the following detailed description in conjunction with the accompanying drawings, in which:

FIG. 1 depicts a flow diagram of a method of fabrication a gate structure in accordance with the present invention;

FIGS. 2A-2F, together, depict a sequence of schematic, cross-sectional views of a substrate having a gate structure being formed in accordance with the method of FIG. 1;

FIG. 3 is a timing diagram of a substrate bias power during etching the gate dielectric layer using the method of FIG. 1 in accordance with one embodiment of the present invention; and

FIG. 4 depicts a schematic diagram of an exemplary plasma processing apparatus of the kind used in performing portions of the method of FIG. 1.

To facilitate understanding, identical reference numerals have been used, where possible, to designate identical elements that are common to the figures.

It is to be noted, however, that the appended drawings illustrate only exemplary embodiments of this invention and are therefore not to be considered limiting of its scope, for the invention may admit to other equally effective embodiments.

### DETAILED DESCRIPTION

The present invention is a method of etching a dielectric layer having a dielectric constant that is greater than 4.0 on a semiconductor substrate. The method uses a pulsed substrate biasing technique (PSBT) that applies a plurality of processing cycles to the substrate, where each cycle comprises a period of plasma etching without substrate bias and a period of plasma etching with the substrate bias.

In one application, the method is used for fabricating a gate structure of a field effect transistor, such as a complementary metal-oxide-semiconductor (CMOS) field effect transistor. A film stack of the gate structure comprises a gate electrode layer and a gate dielectric layer formed on, e.g., a silicon (Si) wafer. A hard mask is used to define the gate structure. When a high-K dielectric material is used as the gate dielectric layer, the high-K dielectric material is generally more difficult to etch than the hard mask. During etching the gate electrode layer, the method increases the etch selectivity of the gate dielectric material (e.g., a difficult to etch material, such as hafnium dioxide (HfO₂), HfSiO₂, and the like) with respect to the material of the hard mask (an easily etched material) and the substrate silicon.

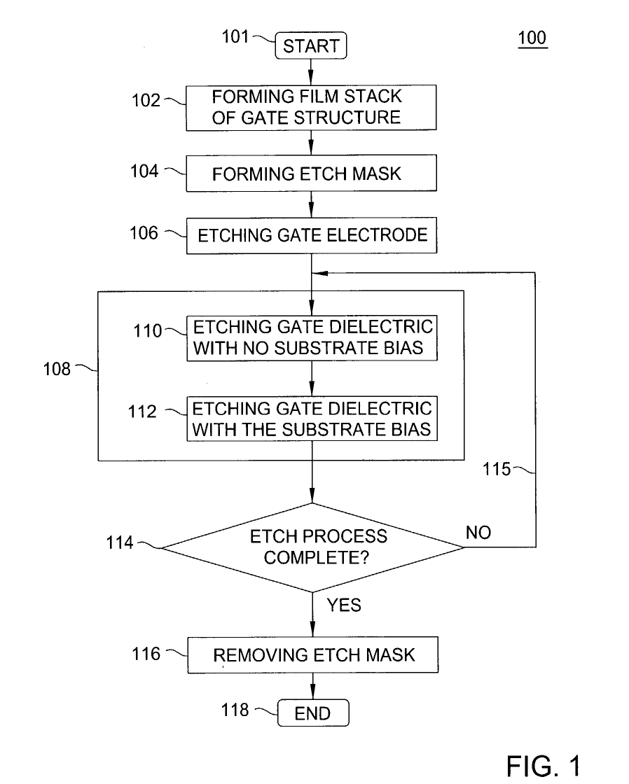

FIG. 1 depicts a flow diagram of a method 100 of fabricating a gate structure in accordance with the present invention. The method 100 comprises processes that are performed upon a film stack of the gate structure during fabrication of a field effect transistor (e.g., CMOS transistor).

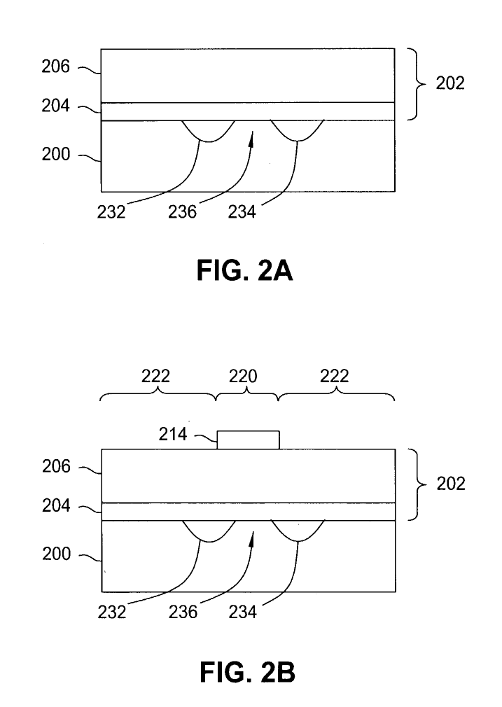

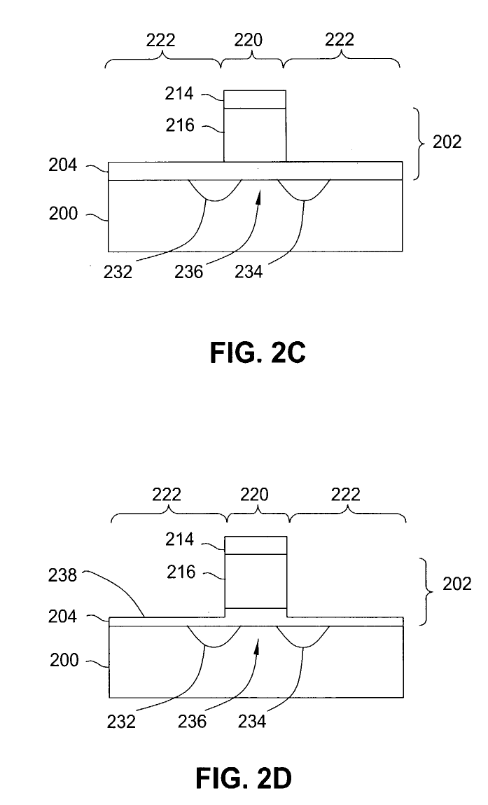

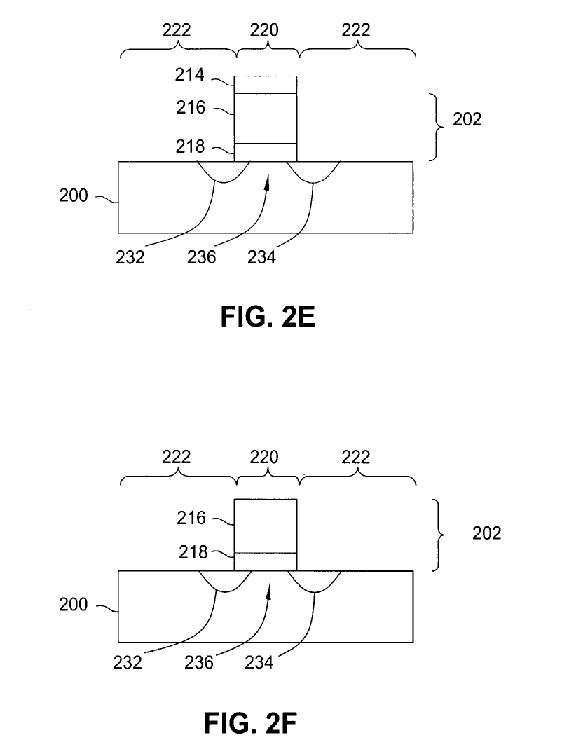

FIGS. 2A-2F, together, depict a sequence of schematic, cross-sectional views of a substrate having a gate structure being formed in accordance with the method 100 of FIG. 1. The cross-sectional views in FIGS. 2A-2F relate to individual processing steps that are used to form the gate structure. Sub-processes, such as lithographic processes (e.g., exposure and development of photoresist, and the like), and wafer cleaning procedures among others are well known in the art and, as such, are not shown in FIG. 1 and FIGS. 2A-2F. The images in FIGS. 2A-2F are not depicted to scale and are simplified for illustrative purposes.

The method 100 starts at step 101 and proceeds to step 102, when a film stack 202 is formed on a wafer 200 (FIG. 2A). The wafer 200, e.g., a silicon (Si) wafer, comprises doped source and drain regions (wells) 232 and 234 that are separated by a channel region 236 of the transistor. In an alternative embodiment (not shown), the wafer 200 may also comprise a thin film (e.g., mono-layer) of silicon dioxide to protect the channel region 236 of the gate structure being formed from diffusive contaminants (e.g., oxygen (O₂) and the like).

The film stack 202 generally comprises an electrode layer 206 and a dielectric layer 204. In one embodiment, the electrode layer 206 is a doped polysilicon (Si) layer formed to a thickness of about 500 to 6000 Angstroms. The dielectric layer 204 is illustratively formed from hafnium dioxide (HfO₂) to a thickness of about 10 to 60 Angstroms. In other embodiments, the layer 204 may comprise at least one film of other materials having a dielectric constant greater than 4.0 (e.g., HfSiO₂ and the like). Herein such materials are referred to as high-K materials. The layers 204 and 206 may be provided using a vacuum deposition technique, such as an atomic layer deposition (ALD), a chemical vapor deposition (CVD), plasma enhanced CVD (PECVD), and the like.

At step 104, a mask 214 is formed on the electrode layer 206 in the region 220 (FIG. 2B). The mask 214 defines location and topographic dimensions of the gate structure being formed using the method 100. Generally, the mask 214 protects the channel region 236 and portions of the source and drain regions 232 and 234, while exposing the adjacent regions 222 of the wafer 200. The mask 214 is a generally a hard mask formed from a material stable at wafer temperatures of at least 500 degrees Celsius used during etching the gate dielectric layer 204 (discussed in reference to step 108 below). Such materials comprise silicon dioxide, inorganic amorphous carbon (i.e., α-carbon), high-K dielectric materials, and the like. Processes for applying the hard mask are described, e.g., in commonly assigned U.S. patent application Ser. No. 10/245,130, filed Sep. 16, 2002 (Attorney docket number 7524) and Ser. No. 09/590,322, filed Jun. 8, 2000 (Attorney docket number 4227), which are incorporated herein by reference.

At step 106, the electrode layer 206 is removed in the regions 222 (FIG. 2C). The remaining portion of the layer 206 forms in the region 220 a gate electrode 216 (e.g., polysilicon gate electrode). Step 106 uses the mask 214 as an etch mask and may use the dielectric layer 204 (e.g., a hafnium dioxide layer) as an etch stop layer. In one illustrative embodiment, step 106 performs a plasma etch process using a gas comprising at least one of chlorinated/brominated/fluorinated chemistries, such as Cl₂, HBr, CF₄, and the like. The process provides a selectivity to polysilicon over HfO₂, HfSiO₂, and the like of about 100:1, as well as selectivity to polysilicon over silicon dioxide and α-carbon mask 214 of about 5:1 and (5-6):1, respectively. Such etch process is disclosed in commonly assigned U.S. patent application Ser. No. 10/194,609, filed Jul. 12, 2002 (Attorney docket number 7365), which is incorporated herein by reference.

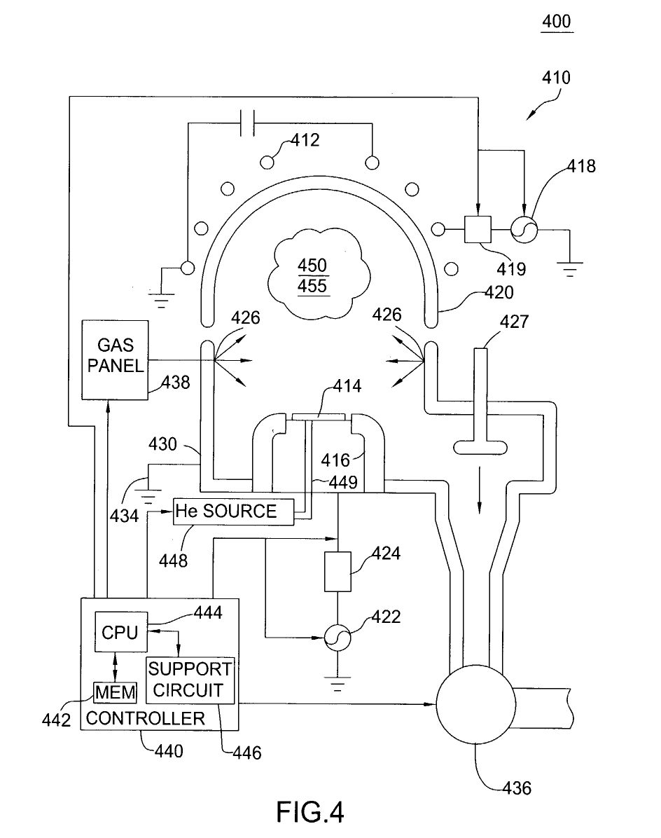

Step 106 can be performed, for example, in a Decoupled Plasma Source (DPS) chamber of the CENTURA® semiconductor wafer processing system available from Applied Materials, Inc. of Santa Clara, Calif. The DPS reactor uses an inductive source to produce a high-density plasma and a source of RF power to bias the wafer. The DPS reactor is described in reference to FIG. 4 below.

In one embodiment, when the polysilicon etch process is performed in the DPS reactor, step 106 provides HBr at a rate of 20 to 300 sccm and chlorine (CO₂) at a rate of 20 to 300 sccm (i.e., a HBr:Cl₂ flow ratio ranging from 1:15 to 15:1), as well as nitrogen (N₂) at a rate of 0 to 200 sccm. Further, step 106 applies 200 to 3000 W of plasma power and 0 to 300 W of bias power and maintains a wafer temperature at 0 to 200 degrees Celsius and a pressure in the reaction chamber at 2 to 100 mtorr. One exemplary process provides HBr at a rate of 40 sccm and Cl₂ at a rate of 40 sccm (i.e., a HBr:Cl₂ flow ratio of 1:1), N₂ at a rate of 20 sccm, 1100 W of plasma power, 20 W of bias power, a wafer temperature of 45 degrees Celsius, and a pressure of 4 mTorr.

At step 108 (FIGS. 2D and 2E), the dielectric layer 204 is removed in the regions 222 using a pulsed substrate biasing technique (PSBT). The PSBT process is an etch process that comprises a period 110 of plasma etching of the dielectric layer 204 with no substrate bias, as well as a period 112 of plasma etching of the dielectric layer 204 with a bias applied to the substrate, e.g., radio-frequency (RF) bias. After the PSBT process, a remaining portion of the dielectric layer 204 forms, in the region 220, a gate dielectric 218 (e.g., a hafnium dioxide gate dielectric). Step 108 uses the mask 214 as an etch mask and may use the silicon substrate 200 as an etch stop layer.

Step 108 may use an etchant gas comprising a halogen gas (e.g., chlorine (Cl₂), HCl, and the like), as well as carbon monoxide (CO) as a reducing gas. Such etch process is disclosed in U.S. patent application Ser. No. 10/194,566, filed Jul. 12, 2002 (Attorney docket number 7269).

A cycle comprising the periods 110 and 112 may be repeated until the dielectric layer 204 is entirely removed in the regions 222 (discussed in reference to step 114 below). The PSBT process may comprise a plurality of such cycles. FIG. 2D depicts the wafer 200 after an intermediate cycle of the PSBT process, while FIG. 2E depicts the wafer upon completion of the process. A duration of the step 108 (i.e., duration of one cycle of the PSBT process) is about 0.1 to 10 msec, while a duration of each of the periods 110 and 112 is about 0.09-9 msec and 0.01-1 msec, respectively. A duty cycle ratio for the period of etching the dielectric layer 204 with the substrate bias (i.e., period 112) is about 20 to 80%. During one exemplary PSBT process, the period 110 has a duration of 12 msec and the period 112 has a duration of 6 msec, which corresponds to a duty cycle of about 33%.

During the period 110, a surface 238 of the dielectric layer 204 is exposed to the etchant gas energized to form a first plasma. In one exemplary embodiment, using the referred to above DPS reactor, the first plasma is produced by an inductively coupled power source, while no bias is applied to the substrate support pedestal (discussed in reference to FIG. 4 below).

The period 110 performs plasma enhanced chemical etching of the dielectric layer 204 while the period does not physically etch (i.e., sputter) the mask 214, gate electrode 216, and dielectric layer 204. The first plasma transforms an upper portion of the layer 204 into volatile compounds that are then pump evacuated from a processing chamber. During the period 110, the surface 238 also absorbs reactive species from the etchant gas. The absorbed species enhance etching the dielectric layer 204 during the following period 112. The period 110 may deposit non-volatile by-products of the etch process upon the surface 238 and elsewhere on the wafer 200. Such by-products should be removed before the etch rate reduces or the etch process self-terminates.

During the period 112, the surface 238 of the layer 208 is exposed to the etchant gas energized to form a second plasma. In the exemplary embodiment, using the DPS reactor, the second plasma is produced by the inductively coupled power source in conjunction with the source of RF bias power coupled to the substrate support pedestal. The second plasma performs simultaneous plasma enhanced chemical etching and physical etching (i.e., sputtering) of the dielectric layer 204, as well as removal of the non-volatile by-products that may remain after the period 110.

Similar to a conventional process of etching the dielectric layer 204, the period 112 also etches the mask 214 and gate electrode 216. However, using the method 100, the losses of material of the mask 214 and gate electrode 216 are reduced with respect to the conventional etch process. The losses are reduced because, during the PSBT process, overall duration of etching the dielectric layer 204 with the substrate bias is shorter and the average bias power is lower than during the conventional etch process. Low losses (i.e., low etch rate) of materials of the mask 214 result in the high selectivity of the PSBT process to the high-K material of the dielectric layer 204 with respect to the materials of the mask and gate electrode. Since etch selectivity to polysilicon is practically the same as that to silicon, the PSBT process also provides high selectivity to the layer 204 (e.g., layer of HfO₂, HfSiO₂, and the like) over the silicon wafer 200. Generally speaking, the PSBT technique provides high selectivity to hard to etch materials (high-K materials, such as HfO₂, HfSiO₂, and the like).

In one embodiment, during etching the hafnium dioxide layer 204 in the DPS reactor, the period 110 provides chlorine at a rate of 2 to 300 sccm, as well as carbon monoxide at a rate of 2 to 200 sccm (i.e., a Cl₂:CO flow ratio ranging from 1:5 to 5:1), applies 200 to 3000 W of plasma power and no bias power, maintains a wafer temperature at 100 to 500 degrees Celsius, and a pressure in the reaction chamber at 2 to 100 mtorr. One exemplary process provides Cl₂ at a rate of 40 sccm and CO at a rate of 40 sccm (i.e., a Cl₂:CO flow ratio of about 1:1), 1100 W from of plasma power, a wafer temperature of 350 degrees Celsius, and a pressure of 4 mTorr.

The period 112 uses the same process recipe as the period 110 and, additionally, applies the RF bias power of about 20 to 500 W at a frequency of about 50 kHz to 13.56 MHz., while one exemplary process applies 50 W at 13.56 MHz.

Such PSBT process provides selectivity to hafnium dioxide over silicon and polysilicon of about 3:1, as well as selectivity to α-carbon of about 5:1. Similarly, the selectivity of the PSBT process to HfSiO₂ over silicon and polysilicon and over α-carbon is about 3:1 and 5:1, respectively.

Because the polysilicon etch process of step 106 is performed at a relatively low temperature, about 40 degrees Celsius, and the PSBT process is performed at a relatively high temperature, about 350 degrees Celsius, each process is generally performed in a separate reactor. However, when the etch reactor has fast temperature control capabilities, both steps 106 and 108 may be performed in such single reactor.

At step 114, the method 100 queries whether the dielectric layer 204 has been removed from the wafer 200 in the regions 222. In a computerized etch reactor, such as the exemplary DPS reactor, at step 114, the decision making routine may be automated using an end-point detection technique. For example, the endpoint detection system of the reactor may monitor plasma emissions at a particular wavelength to determine that the dielectric layer 204 has been removed.

If the query of step 114 is negatively answered, the method 100 proceeds to step 108 to continue the PSBT process, as illustratively shown using a link 115. As such, the PSBT process sequentially performs a plurality of processing cycles. Each processing cycle comprises a period of plasma enhanced chemical etching the dielectric layer 204 (period 110), as well as a period of simultaneous plasma enhanced chemical etching and physical etching the layer 204 (period 112). If the query of step 114 is affirmatively answered, the method 100 proceeds to step 116.

At step 116, the mask 214 is stripped from the gate electrode 216 (FIG. 2F). At step 118, the method 100 ends.

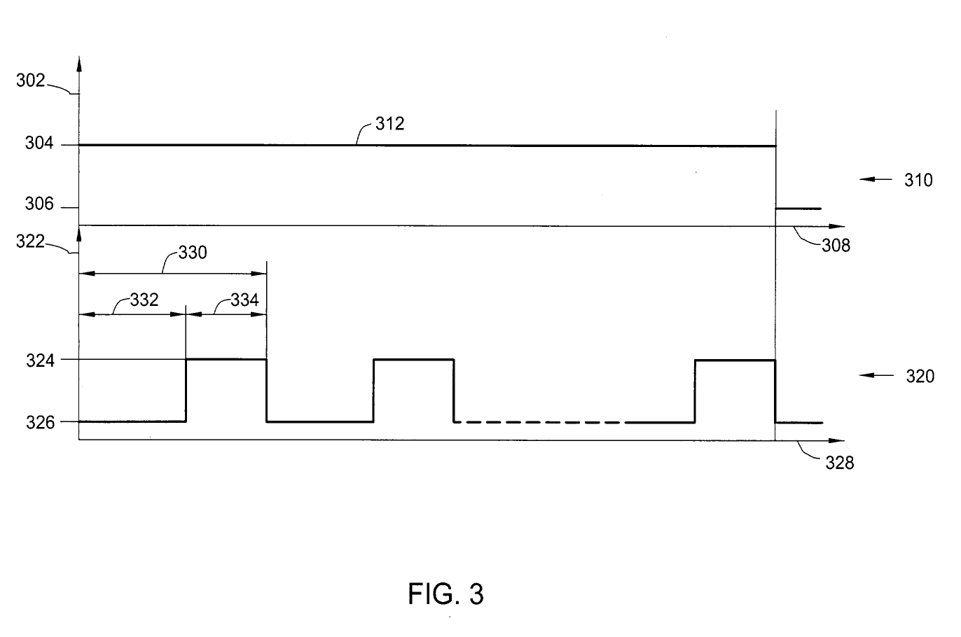

FIG. 3 is an exemplary timing diagram of the PSBT process that may be used to etch, with high selectivity, the dielectric layer 204 (e.g., a layer of HfO₂, HfSiO₂, and the like) of the gate structure, as described above in reference to FIGS. 2D and 2E.

FIG. 3 depicts a sequence of cycles 330 wherein each cycle 330 comprises a period 332 within which an etch process is performed with no substrate bias and a period 334 within which the etch process is performed with the substrate bias. Together, a plurality of cycles 330 comprises a PSBT process 312. A first graph 310 depicts a status (y-axis 302) of the PSBT process, where the PSBT process is in ON (304) and OFF (306) states versus time (x-axis 308). Correspondingly, a second graph 320 (below) depicts a status (y-axis 322) of the substrate bias, where substrate bias is in ON (324) and OFF (326) states versus time (x-axis 328). Specifically, during the time interval 332 of the cycle 330 where the substrate bias is inactive, the etch process performs plasma enhanced chemical etching of the dielectric layer 204. Similarly, during the time interval 334 of the cycle 330 where the substrate bias is active, the PSBT process performs simultaneous plasma enhanced chemical etching and physical etching of the dielectric layer 204. One skilled in the art will understand that the time required, in each cycle 330, to switch between etching without substrate bias and with the substrate bias is not shown.

In FIG. 3, the PSBT process 312 begins with the period 332 and ends with the period 334. Alternatively, the PSBT process 312 may begin with the period 334 and end with the period 332 and/or comprise one or more additional etch periods 332 or 334 at any time during execution of the PSBT process. In the illustrative embodiment where the dielectric layer 204 is formed from hafnium dioxide to a thickness of 50 Angstroms, the PSBT process 312 has a total duration of about 60 to 120 sec. One skilled in the art will appreciate that the duration of the individual periods 332 and 334 may vary during the PSBT process 312 due to various factors, such as layer thickness, layer composition, and the like.

FIG. 4 depicts a schematic diagram of a DPS etch reactor 400 that may be used to practice portions of the inventive method 100. The reactor 400 comprises a process chamber 410 having a wafer support pedestal 416 within a conductive body (wall) 430, and a controller 440.

The support pedestal (cathode) 416 is coupled, through a first matching network 424, to a biasing power source 422. The biasing source 422 generally is a source of up to 500 W at a frequency of approximately 13.56 MHz that is capable of producing either continuous or pulsed power. In other embodiments, the source 422 may be a DC or pulsed DC source. The chamber 410 is supplied with a dome-shaped dielectric ceiling 420. Other modifications of the chamber 410 may have other types of ceilings, e.g., a substantially flat ceiling. Above the ceiling 420 is disposed an inductive coil antenna 412. The antenna 412 is coupled, through a second matching network 419, to a plasma power source 418. The plasma source 418 typically is capable of producing up to 3000 W at a tunable frequency in a range from 50 kHz to 13.56 MHz. Typically, the wall 430 is coupled to an electrical ground 434.

A controller 440 comprises a central processing unit (CPU) 444, a memory 442, and support circuits 446 for the CPU 444 and facilitates control of the components of the DPS etch process chamber 410 and, as such, of the etch process, as discussed below in further detail.

In operation, a semiconductor wafer 414 is placed on the pedestal 416 and process gases are supplied from a gas panel 438 through entry ports 426 and form a gaseous mixture 450. The gaseous mixture 450 is ignited into a plasma 455 in the chamber 410 by applying power from the plasma and bias sources 418 and 422 to the antenna 412 and the cathode 416, respectively. The pressure within the interior of the chamber 410 is controlled using a throttle valve 427 and a vacuum pump 436. The temperature of the chamber wall 430 is controlled using liquid-containing conduits (not shown) that run through the wall 430.

The temperature of the wafer 414 is controlled by stabilizing a temperature of the support pedestal 416. In one embodiment, the helium gas from a gas source 448 is provided via a gas conduit 449 to channels formed by the back of the wafer 414 and grooves (not shown) in the pedestal surface. The helium gas is used to facilitate heat transfer between the pedestal 416 and the wafer 414. During the processing, the pedestal 416 may be heated by a resistive heater (not shown) within the pedestal to a steady state temperature and then the helium gas facilitates uniform heating of the wafer 414. Using such thermal control, the wafer 414 is maintained at a temperature of between 0 and 500 degrees Celsius.

Those skilled in the art will understand that other forms of etch chambers may be used to practice the invention, including chambers with remote plasma sources, microwave plasma chambers, electron cyclotron resonance (ECR) plasma chambers, and the like.

To facilitate control of the process chamber 410 as described above, the controller 440 may be one of any form of general-purpose computer processor that can be used in an industrial setting for controlling various chambers and sub-processors. The memory, or computer-readable medium, 442 of the CPU 444 may be one or more of readily available memory such as random access memory (RAM), read only memory (ROM), floppy disk, hard disk, or any other form of digital storage, local or remote. The support circuits 446 are coupled to the CPU 444 for supporting the processor in a conventional manner. These circuits include cache, power supplies, clock circuits, input/output circuitry and subsystems, and the like. The inventive method is generally stored in the memory 442 as software routine. The software routine may also be stored and/or executed by a second CPU (not shown) that is remotely located from the hardware being controlled by the CPU 444.

Although the forgoing discussion referred to fabricating of the gate structure of a field effect transistor, fabricating of the other structures and features used in the semiconductor integrated circuits and devices can benefit from the invention.

While foregoing is directed to the illustrative embodiment of the present invention, other and further embodiments of the invention may be devised without departing from the basic scope thereof, and the scope thereof is determined by the claims that follow.

What is claimed is:

1. A method of etching a dielectric layer having a dielectric constant that is greater than 4.0 on a semiconductor substrate, comprising:
plasma etching the dielectric layer by applying a plurality of processing cycles to the substrate, where each cycle comprises a period of etching without substrate bias and a period of etching with the substrate bias.

2. The method of claim 1 wherein:
the period of etching the gate dielectric layer without substrate bias has a duration between 0.09 and 9 msec;
the period of etching the gate dielectric layer with the substrate bias has a duration between 0.01 and 1 msec; and
a duty cycle ratio for the period of etching the gate dielectric layer with the substrate bias is about 20 to 80% of a duration of the processing cycle.

3. The method of claim 1 wherein the dielectric layer comprises at least one of HfO₂ and HfSiO₂.

4. The method of claim 3 further comprising during the period of etching the gate dielectric layer without substrate bias:
providing Cl₂ and CO at a flow ratio Cl₂: CO in a range from 1:5 to 5:1; and
maintaining a gas pressure in a range from about 2 to 100 mTorr.

5. The method of claim 3 further comprising during the period of etching the gate dielectric layer with the substrate bias:
providing Cl₂ and CO at a flow ratio Cl₂: CO in a range from 1:5 to 5:1;
applying the substrate bias power between about 20 and 500 W at about 50 kHz to 13.56 MHz; and
maintaining a gas pressure in a range from about 2 to 100 mTorr.

6. The method of claim 3 further comprising:
etching the dielectric layer without substrate bias for a duration of 12 msec applying Cl₂ at a rate of 40 sccm and CO at a rate of 40 sccm, 1100 W to an inductively coupled antenna and 0 W of substrate bias power, and maintaining the substrate support pedestal at 350 degrees Celsius and a pressure on the reaction chamber at 4 mTorr; and
etching the dielectric layer with substrate bias for a duration of 6 msec applying Cl₂ at a rate of 40 sccm and CO at a rate of 40 sccm, 1100 W to an inductively coupled antenna and 50 W of substrate bias power, and maintaining the substrate support pedestal at 350 degrees Celsius and a pressure on the reaction chamber at 4 mTorr.

7. A method of fabricating a gate structure of a field effect transistor on a semiconductor substrate comprising a channel region formed between source and drain regions of said transistor, comprising:
(a) providing a film stack comprising a gate dielectric layer, a gate electrode layer and a patterned mask on the gate electrode layer, said mask is disposed above the channel region;
(b) etching the gate electrode layer; and
(c) plasma etching the gate dielectric layer by applying a plurality of processing cycles to the substrate, where each cycle comprises a period of etching without substrate bias and a period of etching with substrate bias.

8. The method of claim 7 wherein etch selectivity to the gate electrode layer is greater than the etch selectivity to the gate dielectric layer.

9. The method of claim 7 wherein:
the gate electrode layer comprises polysilicon; and
the gate dielectric layer comprises at least one of HfO₂ and HfSiO₂.

10. The method of claim 9 wherein the step (b) further comprises:
providing HBr and Cl₂ at a flow ratio HBr:Cl₂ in a range from 1:15 to 15:1; and
maintaining a gas pressure in a range from about 2 to 100 mTorr.

11. The method of claim 7 wherein the step (c) further comprises:
the period of etching the gate dielectric layer without substrate bias having a duration between 0.09 and 9 msec;
the period of etching the gate dielectric layer with the substrate bias having a duration between 0.01 and 1 msec; and
a duty cycle ratio for the period of etching the gate dielectric layer with the substrate bias is about 20 to 80% of a duration of the processing cycle.

12. The method of claim 9 wherein the step (c) during the period of etching the gate dielectric layer without substrate bias further comprises:
providing Cl₂ and CO at a flow ratio Cl₂:CO in a range from 1:5 to 5:1; and
maintaining a gas pressure in a range from about 2 to 100 mTorr.

13. The method of claim 9 wherein the step (c) during the period of etching the gate dielectric layer with the substrate bias further comprises:
providing Cl₂ and CO at a flow ratio Cl₂: CO in a range from 1:5 to 5:1;
applying the substrate bias power between about 20 and 500 W at about 50 kHz to 13.56 MHz; and
maintaining a gas pressure in a range from about 2 to 100 mtorr.

14. The method of claim 9 wherein the step (c) further comprises:
etching the gate dielectric layer without substrate bias for a duration of 12 msec applying Cl₂ at a rate of 40 sccm and CO at a rate of 40 sccm, 1100 W to an inductively coupled antenna and 0 W of substrate bias power, and maintaining the substrate support pedestal at 350 degrees Celsius and a pressure on the reaction chamber at 4 mTorr; and
etching the gate dielectric layer with the substrate bias for a duration of 6 msec applying Cl₂ at a rate of 40 sccm and CO at a rate of 40 sccm, 1100 W to an inductively coupled antenna and 50 W of substrate bias power, and maintaining the substrate support pedestal at 350 degrees Celsius and a pressure on the reaction chamber at 4 mTorr.

15. The method of claim 7 wherein the step (c) further comprises:
removing the patterned mask.

16. A computer-readable medium including software that, when executed by a processor, performs a method that causes a reactor to etch a dielectric layer having a dielectric constant that is greater than 4.0 on a semiconductor substrate, comprising:
plasma etching the dielectric layer by applying a plurality of processing cycles to the substrate, where each cycle comprises a period of etching without substrate bias and a period of etching with substrate bias.

17. The computer-readable medium of claim 16 wherein:
the period of etching the gate dielectric layer without substrate bias has a duration between 0.09 and 9 msec;
the period of etching the gate dielectric layer with the substrate bias has a duration between 0.01 and 1 msec; and
a duty cycle ratio for the period of etching the gate dielectric layer with the substrate bias is about 20 to 80% of a duration of the processing cycle.

18. The computer-readable medium of claim 16 wherein the dielectric layer comprises at least one of HfO₂ and HfSiO₂.

19. The computer-readable medium of claim 18 further comprising during the period of etching the gate dielectric layer without substrate bias:
providing Cl₂ and CO at a flow ratio Cl₂: CO in a range from 1:5 to 5:1; and
maintaining a gas pressure in a range from about 2 to 100 mTorr.

20. The computer-readable medium of claim 18 further comprising during the period of etching the gate dielectric layer with the substrate bias:
providing Cl₂ and CO at a flow ratio Cl₂: CO in a range from 1:5 to 5:1;
applying the substrate bias power between about 20 and 500 W at about 50 kHz to 13.56 MHz; and
maintaining a gas pressure in a range from about 2 to 100 mTorr.

21. The computer-readable medium of claim 18 further comprising:
etching the dielectric layer without substrate bias for a duration of 12 msec applying Cl₂ at a rate of 40 sccm and CO at a rate of 40 sccm, 1100 W to an inductively coupled antenna and 0 W of substrate bias power, and maintaining the substrate support pedestal at 350 degrees Celsius and a pressure on the reaction chamber at 4 mTorr; and
etching the dielectric layer with the substrate bias for a duration of 6 msec applying Cl₂ at a rate of 40 sccm and CO at a rate of 40 sccm, 1100 W to an inductively coupled antenna and 50 W of substrate bias power, and maintaining the substrate support pedestal at 350 degrees Celsius and a pressure on the reaction chamber at 4 mtorr.
